(19) United States
(12) Patent Application Publication
(10) Pub. No.: US 2019/0343022 A1
(43) Pub. Date: Nov. 7, 2019

(54) TEMPERATURE ACCORDANCE AIRFLOW BALANCING BAFFLE SYSTEM

(71) Applicant: Dell Products L.P., Round Rock, TX (US)

(72) Inventors: Ryan TSENG, Taipei City (TW); Heng-Li CHOU, New Taipei City (TW); Scott JY LIN, Taipei (TW)

(73) Assignee: Dell Products L.P., Round Rock, TX (US)

(21) Appl. No.: 15/971,392

(22) Filed: May 4, 2018

(51) Int. Cl. H05K 7/20; F03G 7/06

(52) U.S. Cl. CPC H05K 7/20618; H05K 7/20181; H05K 7/20145; F03G 7/065

(57) ABSTRACT

An information handling system may include a processor, a memory communicatively coupled to the processor, first and second information handling resources, an air mover configured to provide airflow to the first and second information handling resources, a baffle configured to apportion the airflow between the first and second information handling resources, and a first structural element coupled to the baffle. The first structural element may be proximate to the first information handling resource and may include a shape-memory alloy (SMA). In response to an increase in temperature associated with the first information handling resource, the SMA may be operable to change a physical dimension of the first structural element such that the baffle is moved from a first orientation to a second orientation, the second orientation corresponding to a higher airflow to the first information handling resource.

### TECHNICAL FIELD

The present disclosure relates in general to information handling systems, and more particularly to systems and methods for cooling of information handling systems.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction, and damage leading to a shortened component lifespan. Accordingly, heatsinks and/or air movers (e.g., cooling fans and blowers) have often been used in information handling systems to cool information handling systems and their components.

One challenge that may arise in the cooling context is the efficient distribution of airflow. In particular, airflow generated by one or more air movers may be apportioned among several components, and it is desirable to be able to increase the amount of airflow received by a particular component when that component reaches high temperatures. Conversely, when a component is not at a high temperature, the amount of airflow it receives may be reduced to more optimally distribute the available airflow. Existing baffle systems for distributing airflow, however, tend to be overly complex and subject to various failure modes.

In a server system, for example, PCIe cards are usually installed at the rear of a chassis, downstream of the remainder of the components of the chassis. PCIe cards thus often need to be cooled with hot air based on heat dissipated from such other components. The PCIe inlet ambient temperature of each slot might vary due to placement and workload. For example, the slots directly behind a CPU may have a higher ambient temperature when the system is running programs that stress the CPU than the slots behind storage drives, and vice versa when the system is running the opposite type of workload.

This disclosure thus provides techniques for more simply directing airflow. In particular, airflow baffles according to the present disclosure may in some embodiments operate without the need for electrical or electronic control. Thus a baffle assembly according to this disclosure may in some embodiments not include an electrical input or circuitry configured to change a position of the baffle. Indeed, in some embodiments, a baffle assembly may include no circuitry whatsoever. Thus a self-adjustable baffle system is provided to solve problems relating to uneven airflow and internal ambient temperature distribution. This disclosure includes an adjustable air-baffle system, and the adjustment may be made automatic by means of a shape-memory alloy material in some embodiments.

It should be noted that the discussion of a technique in the Background section of this disclosure does not constitute an admission of prior-art status. No such admissions are made herein, unless clearly and unambiguously identified as such.

### SUMMARY

In accordance with the teachings of the present disclosure, the disadvantages and problems associated with cooling of information handling systems may be reduced or eliminated.

In accordance with embodiments of the present disclosure, an information handling system may include a processor, a memory communicatively coupled to the processor, first and second information handling resources, an air mover configured to provide airflow to the first and second information handling resources, a baffle configured to apportion the airflow between the first and second information handling resources, and a first structural element coupled to the baffle. The first structural element may be proximate to the first information handling resource and may include a shape-memory alloy (SMA). In response to an increase in temperature associated with the first information handling resource, the SMA may be operable to change a physical dimension of the first structural element such that the baffle is moved from a first orientation to a second orientation, the second orientation corresponding to a higher airflow to the first information handling resource

In accordance with these and other embodiments of the present disclosure, a method may include forming a baffle from a baffle material, wherein, when installed in an information handling system, the baffle is configured to apportion an airflow between first and second information handling resources of the information handling system. The method may further include coupling a first structural element comprising a shape-memory alloy (SMA) to the baffle such that, when installed in the information handling system, the first structural element is configured to be proximate to the first information handling resource. Further, in response to an increase in temperature associated with the first information handling resource, the SMA may be operable to change a physical dimension of the first structural element such that the baffle is moved from a first orientation to a second orientation, the second orientation corresponding to a higher airflow to the first information handling resource.

In these and other embodiments of the present disclosure, an apparatus may include a baffle configured to apportion airflow between first and second information handling resources of an information handling system, and a first structural element coupled to the baffle, the first structural element being proximate to the first information handling resource and comprising a shape-memory alloy (SMA). In response to an increase in temperature associated with the first information handling resource, the SMA may be operable to change a physical dimension of the first structural element such that the baffle is moved from a first orientation to a second orientation, the second orientation corresponding to a higher airflow to the first information handling resource.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system, in accordance with embodiments of the present disclosure;

FIGS. 2A and 2B illustrate an example baffle, in accordance with embodiments of the present disclosure;

FIG. 3 illustrates another example baffle, in accordance with embodiments of the present disclosure; and

FIGS. 4A and 4B illustrate yet another example baffle, in accordance with embodiments of the present disclosure.

### DETAILED DESCRIPTION

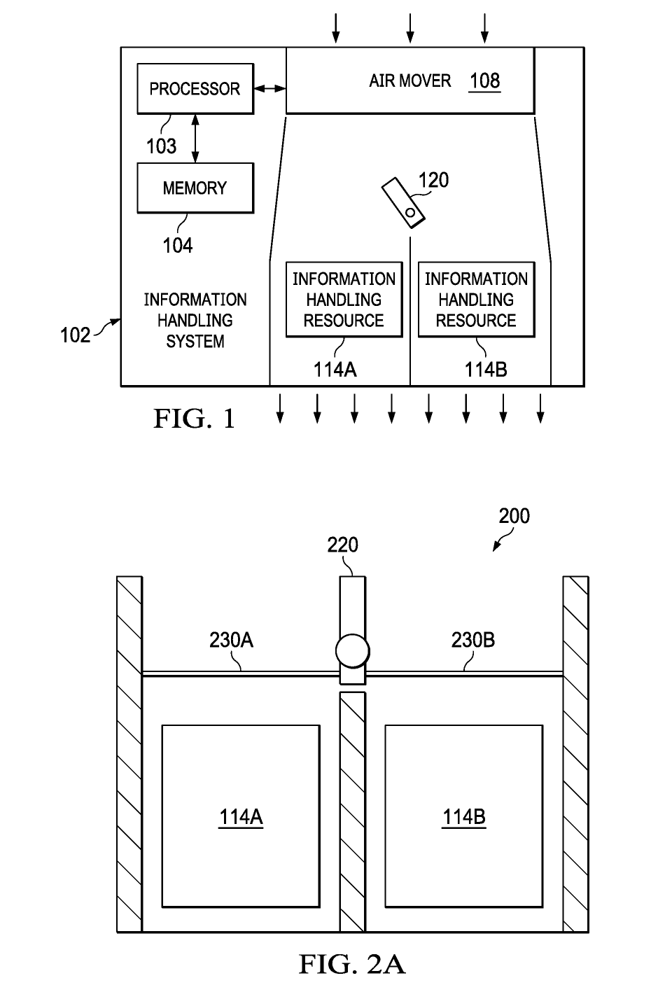

Preferred embodiments and their advantages are best understood by reference to FIGS. 1 through 4B, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and may vary in size, shape, performance, functionality, and price. The information handling system may include memory, one or more processing resources such as a central processing unit (“CPU”) or hardware or software control logic. Additional components of the information handling system may include one or more storage devices, one or more communications ports for communicating with external devices as well as various input/output (“I/O”) devices, such as a keyboard, a mouse, and a video display. The information handling system may also include one or more buses operable to transmit communication between the various hardware components.

For purposes of this disclosure, when two or more elements are referred to as “coupled” to one another, such term indicates that such two or more elements are in electronic communication or mechanical communication, as applicable, whether connected indirectly or directly, with or without intervening elements.

When two or more elements are referred to as “coupleable” to one another, such term indicates that they are capable of being coupled together.

For the purposes of this disclosure, computer-readable media (e.g., transitory or non-transitory computer-readable media) may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, service processors, basic input/output systems, buses, memories, I/O devices and/or interfaces, storage resources, network interfaces, motherboards, and/or any other components and/or elements of an information handling system.

For the purposes of this disclosure, a shape-memory alloy (SMA) may refer to any of a variety of metals that have the property that, after having been deformed, they are operable to return to their pre-deformed shape when heated to some trigger temperature. Such alloys are also commonly referred to as “memory metals” or the like. Various alloys have this property, to greater or lesser extents, and based on differing trigger temperatures. Some examples of SMAs include copper-aluminum-nickel and nickel-titanium. The physics of SMAs will be understood by one of ordinary skill in the art with the benefit of this disclosure, and so they are not described in detail herein. One of ordinary skill in the art with the benefit of this disclosure will readily be able to select a suitable type of SMA (e.g., having a desired trigger temperature) for any given application described herein.

FIG. 1 illustrates a block diagram of an example information handling system 102, in accordance with the present disclosure. In some embodiments, information handling system 102 may comprise a server chassis configured to house a plurality of servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data (which may generally be referred to as “physical storage resources” herein). As shown in FIG. 1, information handling system 102 may comprise a processor 103, a memory 104, one or more air movers 108, information handling resources 114A and 114B, and a baffle assembly 120.

Processor 103 may include any system, device, or apparatus configured to interpret and/or execute program instructions and/or process data, and may include, without limitation, a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may include any system, device, or apparatus configured to retain program instructions and/or data for a period of time (e.g., computer-readable media). Memory 104 may include RAM, EEPROM, a PCMCIA card, flash memory, magnetic storage, opto-magnetic storage, or any suitable selection and/or array of volatile or non-volatile memory that retains data after power to information handling system 102 is turned off.

Memory 104 may have stored thereon an operating system. Such an operating system may comprise any program of executable instructions, or aggregation of programs of executable instructions, configured to manage and/or control the allocation and usage of hardware resources such as memory, processor time, disk space, and input and output devices, and provide an interface between such hardware resources and application programs hosted by the operating system. In addition, the operating system may include all or a portion of a network stack for network communication via a network interface (e.g., one of devices 114 may be a network interface for communication over a data network). Although the operating system may be stored in memory 104, in some embodiments it may be stored in storage media accessible to processor 103, and active portions of the operating system may be transferred from such storage media to memory 104 for execution by processor 103.

Air mover 108 may be communicatively coupled to an air mover control system, and may include any mechanical or electro-mechanical system, apparatus, or device operable to move air and/or other gases. In some embodiments, air mover 108 may comprise a fan (e.g., a rotating arrangement of vanes or blades which act on the air). In other embodiments, air mover 108 may comprise a blower (e.g., centrifugal fan that employs rotating impellers to accelerate air received at its intake and change the direction of the airflow). In these and other embodiments, rotating and other moving components of air mover 108 may be driven by a motor 110. The rotational speed of motor 110 may be controlled by the air mover control signal communicated from an air mover control system. In operation, air mover 108 may cool information handling resources of information handling system 102 by drawing cool air into an enclosure housing the information handling resources from outside the chassis, expelling warm air from inside the enclosure to the outside of such enclosure, and/or moving air across one or more heatsinks (not explicitly shown) internal to the enclosure to cool one or more information handling resources.

In some embodiments, a management controller (not shown) may be used to implement various types of cooling strategies by air mover 108. Some examples of such cooling strategies are disclosed in U.S. Patent Publication No. 2017/0329651, which is incorporated by reference herein in its entirety.

Information handling resources 114A and 114B (which may also be referred to collectively simply as “information handling resources 114”) may be communicatively coupled to processor 103 and may generally include any information handling resource. In some embodiments, information handling resources 114 may include devices that, in operation, produce a substantial amount of heat. For example, information handling resources 114 may include processors, physical storage resources, entire blade servers, etc. in various embodiments.

Such a management controller may be configured to provide out-of-band management facilities for management of information handling system 102. Such management may be made by the management controller even if information handling system 102 is powered off or powered to a standby state. The management controller may include a processor, memory, an out-of-band network interface separate from and physically isolated from an in-band network interface of information handling system 102, and/or other embedded information handling resources. In certain embodiments, the management controller may include or may be an integral part of a baseboard management controller (BMC) or a remote access controller (e.g., a Dell Remote Access Controller or Integrated Dell Remote Access Controller). In other embodiments, the management controller may include or may be an integral part of a chassis management controller (CMC).

As shown in FIG. 1, air mover 108 provides airflow to information handling resources 114A and 114B. Information handling resources 114A and 114B may be the same type of resource, or they may be different types of resource. In some embodiments, they may be PCIe devices received in PCIe slots of information handling system 102 In operation, it may be desirable to maintain an appropriate level of cooling for information handling resources 114, including increasing or decreasing cooling as appropriate.

Baffle assembly 120 is disposed in the path of this airflow and is operable to apportion the airflow between information handling resources 114A and 114B either equally or unequally. For example, in the illustrated situation, baffle assembly 120 is providing more airflow to information handling resource 114B than 114A. By suitably rotating and/or translating, baffle assembly 120 may provide different apportionments of airflow. The respective air paths for information handling resources 114 are referred to herein as “tunnels” in some embodiments. Various embodiments of implementations of baffle assembly 120 are described in more detail below.

In addition to baffle assembly 120, processor 103, memory 104, air mover 108, and information handling resources 114, information handling system 102 may include one or more other information handling resources.

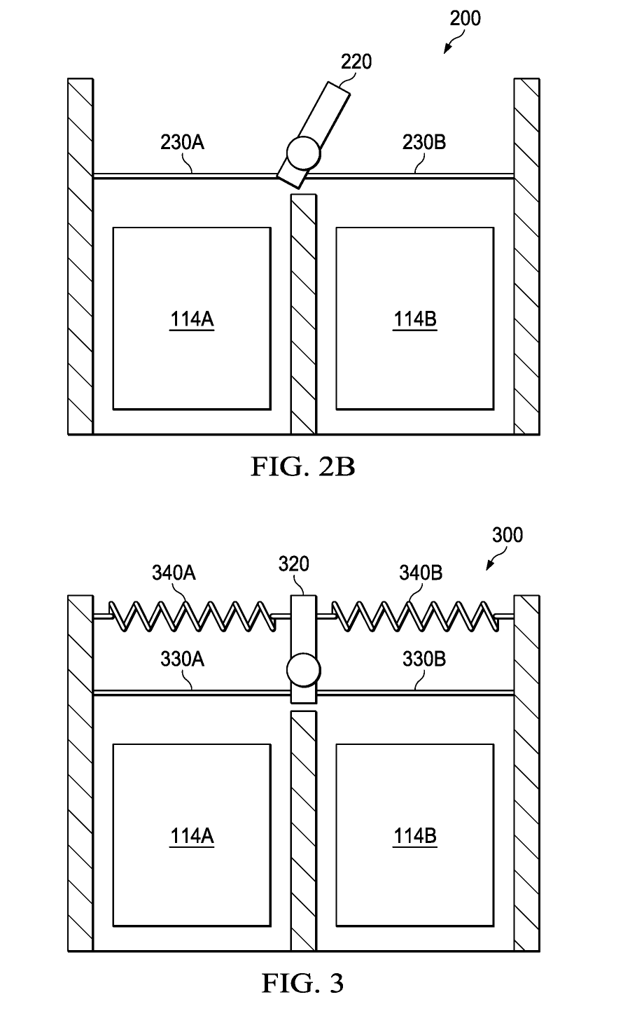

Turning now to FIGS. 2A and 2B, an embodiment of baffle assembly 200 is shown, which may be used to implement the baffle assembly 120 of FIG. 1. Although not shown explicitly in FIGS. 2A-4B, airflow is in the top-to-bottom direction, as in FIG. 1. Such airflow may be provided by one or more air movers, which are also not shown explicitly in these FIGURES.

Baffle assembly 200 includes baffle 220 and two structural elements 230A and 230B. Structural elements 230 may be made of an SMA, and in operation, they may function as actuators to adjust the position of baffle 220. In this embodiment, structural elements 230 may shrink in response to increased temperature.

In this embodiment, heating of either structural element 230 will tend to cause that structural element to contract. In particular, a high inlet ambient temperature of one tunnel (or proximity to a particularly hot information handling resource 114) may cause that SMA to reach its trigger point. That SMA may then contract to rotate baffle 220 about its shaft and widen the tunnel that has the higher inlet ambient to enhance cooling by increasing its airflow rate.

If both tunnels reach the SMA trigger point, baffle 220 may tend to move back to a balanced location by the opposing forces of the two SMA structural elements, and both tunnels may receive a substantially equal airflow. FIG. 2A illustrates the situation where both tunnels are at a similar temperature, and so the baffle is in an intermediate position to provide equal airflow to both sides. (In other embodiments, the baseline position need not be equally balanced, but may, for example, favor a particular type of information handling resource with additional cooling.) FIG. 2B illustrates the situation where information handling resource 114A (or its inlet ambient temperature) is hot enough to trigger the SMA of structural element 230A, causing structural element 230A to contract, providing additional airflow to information handling resource 114A.

As will be understood by one of ordinary skill with the benefit of this disclosure, the situation that is opposite to FIG. 2B may also occur. That is, if information handling resource 114B is hot enough to trigger an SMA, then structural element 230B may contract, providing additional airflow to information handling resource 114B.

Turning now to FIG. 3, a similar embodiment is shown. Baffle assembly 300 includes baffle 320 and two structural elements 330A and 330B, which may be made of SMA. Baffle assembly 300 further includes springs 340A and 340B. In some embodiments, different types of springs (or springs with differing spring constants) may be used to provide a biasing force in one direction or the other. Springs 340 may generally be referred to as biasing springs.

Further, the addition of springs 340A and 340B may provide additional benefits as compared with the embodiment of FIGS. 2A-2B. For example, if structural element 330A has reached its SMA critical temperature but structural element 330B has not, structural element 330B may be in a relatively compliant state. The addition of springs 340 may allow more efficient recovery to the rest position of baffle 320 by providing at all times a restoring force, regardless of the temperatures of structural elements 330A and 330B.

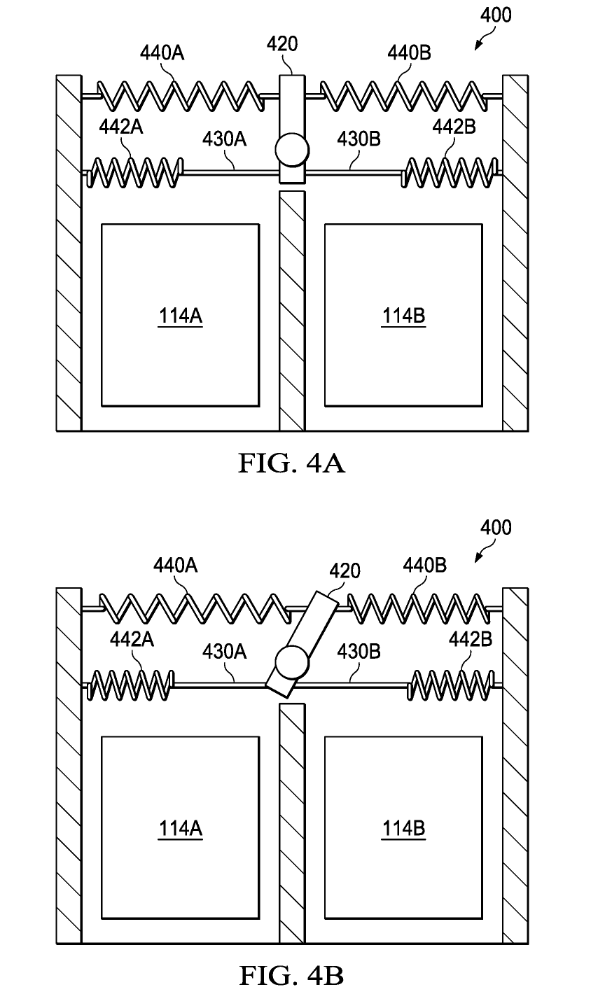

Turning now to FIGS. 4A and 4B, a similar embodiment is shown. Baffle assembly 400 includes baffle 420 and two structural elements 430A and 430B, which may be made of SMA. Baffle assembly 400 further includes springs 440A and 440B, which may be similar or dissimilar in construction to springs 340A and 340B. In this embodiment, baffle assembly 400 further includes series springs 442A and 442B coupled in series with structural elements 430A and 430B respectively.

In this embodiment, when the system is at a relatively low temperature and the SMAs have not reached their trigger point, both structural elements 430 may be extended by their respective series springs 442. This situation is shown in FIG. 4A.

In activated mode (shown at FIG. 4B), information handling system 114A or its inlet ambient is at a sufficiently high temperature to activate the SMA of structural element 430A, shrinking structural element 430A. Structural element 430A may then be short enough to extend series spring 442A to provide a pulling force against springs 440A and 440B to adjust the position of baffle 420. Meanwhile, the SMA of structural element 430B may be un-activated and extended further by the action of series spring 442A.

This disclosure encompasses all changes, substitutions, variations, alterations, and modifications to the exemplary embodiments herein that a person having ordinary skill in the art would comprehend. Similarly, where appropriate, the appended claims encompass all changes, substitutions, variations, alterations, and modifications to the exemplary embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

All examples and conditional language recited herein are intended for pedagogical objects to aid the reader in understanding the invention and the concepts contributed by the inventor to furthering the art, and are construed as being without limitation to such specifically recited examples and conditions. Although embodiments of the present inventions have been described in detail, it should be understood that various changes, substitutions, and alterations could be made hereto without departing from the spirit and scope of the disclosure.

What is claimed is:

1. An information handling system comprising:
a processor;
a memory communicatively coupled to the processor;
first and second information handling resources;
an air mover configured to provide airflow to the first and second information handling resources;
a baffle configured to apportion the airflow between the first and second information handling resources; and
a first structural element coupled to the baffle, the first structural element being proximate to the first information handling resource and comprising a shape-memory alloy (SMA);
wherein, in response to an increase in temperature associated with the first information handling resource, the SMA is operable to change a physical dimension of the first structural element such that the baffle is moved from a first orientation to a second orientation, the second orientation corresponding to a higher airflow to the first information handling resource.

2. The information handling system of claim 1, further comprising a second structural element coupled to the baffle, the second structural element comprising the SMA.

3. The information handling system of claim 2, wherein in response to an increase in temperature associated with the second information handling resource, the SMA is operable to change a physical dimension of the second structural element such that the baffle is moved from the second orientation to the first orientation, the first orientation corresponding to a higher airflow to the second information handling resource.

4. The information handling system of claim 1, further comprising a biasing spring coupled to the baffle.

5. The information handling system of claim 4, further comprising a plurality of biasing springs coupled to the baffle.

6. The information handling system of claim 1, wherein the information handling system does not include circuitry that is configured to alter the orientation of the baffle.

7. The information handling system of claim 1, wherein the baffle does not include an electrical input.

8. The information handling system of claim 1, wherein the second orientation further corresponds to a lower airflow to the second information handling resource.

9. A method comprising:
forming a baffle from a baffle material, wherein, when installed in an information handling system, the baffle is configured to apportion an airflow between first and second information handling resources of the information handling system; and
coupling a first structural element comprising a shape-memory alloy (SMA) to the baffle such that, when installed in the information handling system, the first structural element is configured to be proximate to the first information handling resource;
wherein, in response to an increase in temperature associated with the first information handling resource, the SMA is operable to change a physical dimension of the first structural element such that the baffle is moved from a first orientation to a second orientation, the second orientation corresponding to a higher airflow to the first information handling resource.

10. The method of claim 9, wherein the baffle material is a plastic material.

11. The method of claim 9, further comprising a second structural element comprising the SMA to the baffle such that, when installed in the information handling system, the second structural element is configured to be proximate to the second information handling resource.

12. The method of claim 11, wherein in response to an increase in temperature associated with the second information handling resource, the SMA is operable to change a physical dimension of the second structural element such that the baffle is moved from the second orientation to the first orientation, the first orientation corresponding to a higher airflow to the second information handling resource.

13. The method of claim 9, wherein the second orientation further corresponds to a lower airflow to the second information handling resource.

14. An apparatus comprising:
a baffle configured to apportion airflow between first and second information handling resources of an information handling system; and
a first structural element coupled to the baffle, the first structural element being proximate to the first information handling resource and comprising a shape-memory alloy (SMA);
wherein, in response to an increase in temperature associated with the first information handling resource, the SMA is operable to change a physical dimension of the first structural element such that the baffle is moved from a first orientation to a second orientation, the second orientation corresponding to a higher airflow to the first information handling resource.

15. The apparatus of claim 14, wherein the movement from the first orientation to the second orientation includes a rotation of the baffle.

16. The apparatus of claim 14, wherein the movement from the first orientation to the second orientation includes a translation of the baffle.

17. The apparatus of claim 14, further comprising a second structural element coupled to the baffle, the second structural element comprising the SMA

18. The apparatus of claim 14, further comprising a biasing spring coupled to the baffle.

19. The apparatus of claim 14, further comprising a plurality of springs coupled to the baffle.

20. The apparatus of claim 14, wherein the apparatus does not include circuitry operable to change the orientation of the baffle.
